(19) United States
(12) Patent Application Publication
(10) Pub. No.: US 2025/0007207 A1
(43) Pub. Date: Jan. 2, 2025

(54) Heatsink and Connector Assembly

(71) Applicant: Tyco Electronics (Shanghai) Co., Ltd., Shanghai (CN)

(72) Inventors: Tao Peng, Shanghai (CN); Guangming (Suny) Zhao, Shanghai (CN); WenYu (Vindy) Liu, Shanghai (CN)

(73) Assignee: Tyco Electronics (Shanghai) Co., Ltd., Shanghai (CN)

(21) Appl. No.: 18/757,870

(22) Filed: Jun. 28, 2024

(30) Foreign Application Priority Data
Jun. 29, 2023 (CN) 202310789097.8

(51) Int. Cl. H01R 13/533; F28D 21/00; F28F 3/06

(52) U.S. Cl. CPC H01R 13/533; F28F 3/06; F28D 2021/0029; F28F 2215/14

(57) ABSTRACT

A heatsink adapted to be installed on a housing of a connector includes at least one heat sink assembly. The heat sink assembly has a plurality of heatsink fins extending in a longitudinal direction thereof. The plurality of heatsink fins are stacked in a spaced manner in a width direction of the heatsink assembly and assembled together to define an air passage extending in the longitudinal direction between adjacent heatsink fins. At least one of a plurality of air passages defined by the plurality of heatsink fins is sized to allow a longitudinally extending heat generation device to at least partially pass through and be positioned within a corresponding one of the at least one air passage.

### CROSS-REFERENCE TO RELATED APPLICATION

This application claims the priority benefit of Chinese Patent Application No. CN202310789097.8 filed on Jun. 29, 2023, in the China National Intellectual Property Administration, the whole disclosure of which is incorporated herein by reference.

### FIELD OF THE INVENTION

Embodiments of the present disclosure generally relate to the field of electrical connectors, and more particularly, to a heatsink with improved a heat dissipation effect, and a connector assembly including the same.

### BACKGROUND

Heat generated during operation of a connector, such as a high-speed electrical connector or optoelectronic connector, will reduce the electrical performance of an associated electric apparatus. For this purpose, a heatsink is usually installed on a housing of the connector to reduce the temperature of the electric apparatus. The connector typically includes a housing, a terminal module, and a heatsink. The terminal module is accommodated in the housing and adapted to be connected with an inserted mating module. The heatsink is installed on the housing to dissipate heat from the connector. In addition to heat generated from the terminal module and mating module during operation, other connection devices, which are connected to the terminal module or mating module for electrical or optical communication will also generate heat. Heat dissipation is also required for these connection devices.

In the prior art, due to differences in the size, design, and installation position of the housing of the connector and the heatsink, as well as in the layout design of a plurality of heatsink fins constituting a single heatsink assembly, and due to component cost factors, a spacing between heatsink fins is uniform. This is not suitable for accepting additional heat generation devices therein. As a result, a combination of a plurality of heatsink assemblies has to be adopted to dissipate heat from the heat generation device, resulting in an increase in cost. However, if the heat generation device is placed on a side of the heatsink assembly or near the heatsink assembly, it will lead to insufficient heat dissipation and reduce an effective heat dissipation width of the heatsink assembly. This results in a decrease in heat dissipation performance.

### SUMMARY

According to an embodiment of the present disclosure, a heatsink adapted to be installed on a housing of a connector includes at least one heat sink assembly. The heat sink assembly has a plurality of heatsink fins extending in a longitudinal direction thereof. The plurality of heatsink fins are stacked in a spaced manner in a width direction of the heatsink assembly and assembled together to define an air passage extending in the longitudinal direction between adjacent heatsink fins. At least one of a plurality of air passages defined by the plurality of heatsink fins is sized to allow a longitudinally extending heat generation device to at least partially pass through and be positioned within a corresponding one of the at least one air passage.

### BRIEF DESCRIPTION OF THE DRAWINGS

The invention will now be described by way of example with reference to the accompanying Figures, of which:

FIG. 1 is a perspective view schematically showing a structure of a connector assembly according to an exemplary embodiment of the present application;

FIG. 2 is a side view schematically showing a structure of a connector assembly according to an exemplary embodiment of the present application;

FIG. 3 is an end view schematically showing a structure of a connector assembly according to an exemplary embodiment of the present application;

FIG. 4 is an exploded view schematically showing a structure of a connector assembly according to an exemplary embodiment of the present application; and

FIG. 5 is an exploded view schematically showing a structure of heatsink fins according to an exemplary embodiment of the present application, wherein the heatsink fins are in a state before assembling.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to the exemplary embodiments of the present disclosure, a connector assembly is provided and includes a heatsink. The heatsink comprises a plurality of heatsink fins arranged to allow a heating generation device to be positioned therebetween, improving a heat dissipation effect of the heatsink. Accordingly, the connector assembly is adapted to be used, for example, in a variety of connectors with higher heat dissipation requirements, such as an electrical connector, an optoelectronic connector, a high-speed data connector, or the like.

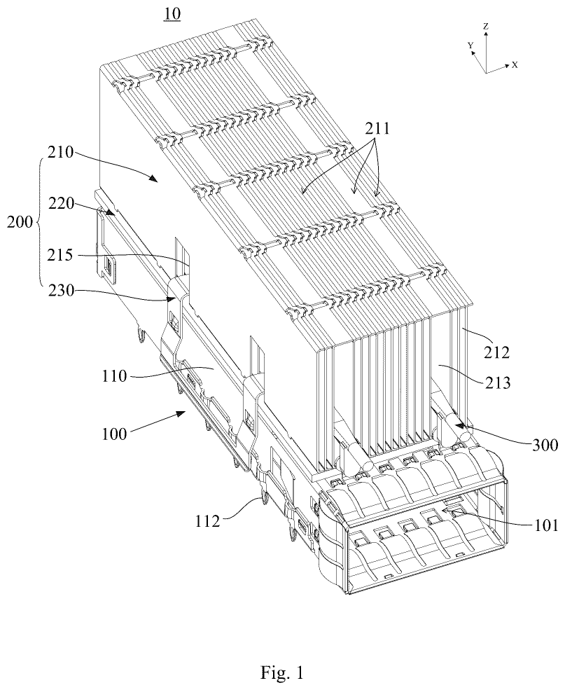

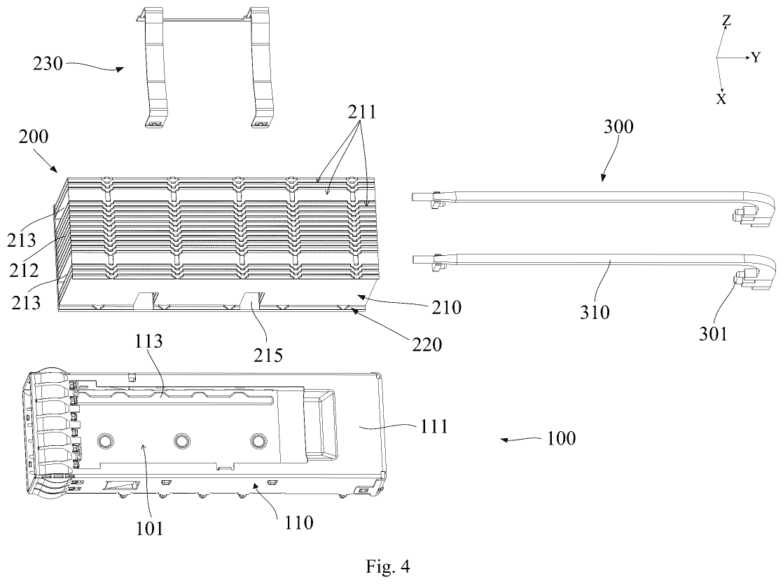

More specifically, as shown in FIGS. 1-4, a connector assembly 10 includes a connector 100 including a housing 110 and a connector module such as a terminal module. The housing 110, for example, has a roughly hexahedral form or a roughly rectangular cross-section, and defines an accommodating cavity 101. The connector module of the connector 100 itself is provided in the accommodating cavity 101. At least an insertion module or interconnection component, such as an electrical connection module, an optical module such as a fiber plug, a photoelectric converter, or a pluggable transceiver, of a mating connector, which is to be mated or connected with the connector module, may also be accommodated, or received in the accommodating cavity 101. In this way, electrical connection, communication connection, or optical coupling connection between the two mating connectors is realized.

The connector assembly 10 is adapted to be installed in an electric apparatus such as a router or server. For example, the connector assembly may be installed and fixed on a circuit board (not shown) of the electric apparatus via an installation leg 112 of the housing 110. As a further example, the connector 100 may be a socket connector which is engageable with a plug connector such as a pluggable transceiver. The connector 100 may be adapted to be used in a data communication system, such as being able to execute one or more communication protocols, including but not necessarily limited to Ethernet, fiber passage, infinite bandwidth technology, and Synchronous Optical Network/Synchronous Digital Hierarchy. For example, the connector assembly 10 may be physically configured (e.g., sized and/or shaped) to meet industry standards or other small factor standards for Small Factor Pluggable, Enhanced SFP, Quad SFP, Micro QSFP, C-Factor Pluggable (CFP), and 10 Gigabit SFP (generally referred to as CFP).

As shown in the figures, the connector assembly 10 further includes a heatsink 200 installed on the housing 110. The heatsink 200 may be installed on a surface of the housing 110 to at least absorb heat from the connector module or insertion module positioned in the accommodating cavity 101 of the housing 110 and dissipate the absorbed heat into the surrounding environment. The heatsink 200 includes a heatsink assembly 210 which is fixed on an installation surface 111 of the housing 110, for example. Although in the illustrated embodiments, the heatsink 200 or heatsink assembly 210 is installed on a top wall of the housing 110, but present disclosure is not limited thereto, and in other embodiments, the heatsink or heatsink assembly may also be provided on a side wall of the housing to meet the space requirements of different connector arrangements.

The heatsink assembly 210 extends longitudinally in a length of the housing 110 and includes a plurality of heatsink fins 211. Each of the fins 211 extends in a longitudinal direction Y and a height direction Z of the heatsink assembly 210, for example, forming a roughly plate-shaped shape. The plurality of heatsink fins 211 are stacked and assembled in a spaced manner in a width direction X of the heatsink assembly 210, so that an air passage extending in the longitudinal direction Y is defined between adjacent heatsink fins 211. External air flow flows into the air passage between the adjacent heatsink fins 211 to take away the heat absorbed or exchanged by the heatsink 200 and/or its heatsink fins 211 from the connector module or insertion module. Herein, the heatsink assembly refers to a single or integrated heatsink unit that includes a plurality of heatsink fins assembled together, and the heatsink may include a plurality of such heatsink assemblies or units, which may be installed or arranged on the same housing or heat transferring base plate, but there is no connection relationship between the heatsink fins of the adjacent heatsink assemblies or units.

In exemplary embodiments of the present disclosure, it is possible to additionally arrange other devices, which will generate heat and will be referred to as heat generation device 300, in the air passage between the heatsink fins of the heatsink 200. The devices may be at least partially arranged on an outside of the housing, and may include, for example, a connecting device for electrical connection or optical communication with the connector module of the connector 100 or the insertion module of the mating connector, such as a light guide tube, in order to facilitate heat dissipation of the heat generation device.

In the heatsink assembly 210, at least one air passage of the plurality of air passages defined by the plurality of heatsink fins 211 of the heatsink assembly 210 is sized to allow the heat generation device 300, which extends in the longitudinal direction Y, to at least partially pass therethrough and be positioned within a corresponding one of the at least one air passage. That is, the heat generation device 300 may be arranged at least partially within the air passage between the adjacent heatsink fins 211 of the same heatsink assembly 210 to improve the heat dissipation effect. As an example, as shown in FIGS. 1-4, the heat generation device 300 includes an elongate main body portion 310 extending in the longitudinal direction Y. An end of the main body portion 310 may be formed or provided with an interface portion 301, which may be partially positioned within the accommodating cavity 101 and adapted to be connected with the connector module arranged within the housing 110 or with the insertion module of the mating connector. A majority of the main body portion 310 is adapted to be positioned within the air passage having the aforementioned size, for example, the size may be greater than or equal to a width of the main body portion 310.

In an exemplary embodiment, the size of the other air passages of the plurality of air passages defined by the plurality of heatsink fins 211 of the heatsink assembly 210 in the width direction X may differ from the size of the at least one air passage in the width direction X. This prevents the heat generation device 300 from being inserted and positioned within the other air passages, thereby avoiding mis-insertion. For example, the size of the at least one air passage, into which the heat generation device 300 is inserted, in the width direction X is larger than the size of the other air passages in the width direction X, and the size of the other air passages in the width direction X is smaller than the width of the heat generation device 300. In some examples, a position of the air passage, into which the heat generation device 300 is adapted or allowed to be inserted, may be consistent with, for example aligned with in the longitudinal direction Y, a position where the heat generation device 300 will be connected to the connector module of the connector 100 or the insertion module of the mating connector, so as to facilitate assembly.

In the illustrated embodiments, the plurality of air passages include a plurality of first passages 212 and at least one second passage 213. A size of each second passage 213 in the width direction is formed to allow the heat generation device 300 to at least partially pass through and be positioned within the second passage, and the size or width of the first passage 212 in the width direction X is smaller than that of the second passage 213 in the width direction X, thereby only allowing the heat generation device 300 to be positioned within the second passage 213 with a larger size or width, without being inserted or positioned within the first passage 212 with a smaller size or width. Illustratively, according to the actual arrangement requirements of the heatsink fins, the sizes, or widths of the plurality of first passages 212 in the width direction may be the same or different from each other.

In the embodiments shown in FIGS. 1, 3, and 4, each second passage 213 may be positioned between adjacent first passages 212 in the width direction X. However, the present disclosure is not limited to this. In other embodiments, the second passage may also be the outermost air passage of the heatsink assembly in the width direction.

In the specific examples illustrated, the heatsink assembly 210 includes two second passages 213 spaced apart in the width direction X for the insertion of two heat generation devices 300 therein. The number of the first passages 212 between the two second passages 213 may be more than the number of the first passages 212 positioned outside of each second passage 213. However, the present disclosure is not limited to this, and the positions of the first and second passages may be flexibly arranged according to actual needs.

In some embodiments, the plurality of heatsink fins 211 of each heatsink assembly 210 may be fixedly assembled together relative to each other, so that spacings or intervals between the plurality of heatsink fins 211 in the width direction X are constant. That is, the sizes or widths of the first passage 212 and the second passage 213 in the width direction X are constant.

In some other embodiments, the spacings or intervals between the plurality of heatsink fins 211 of each heatsink assembly 210 in the width direction X may be adjusted or variable. For example, the plurality of heatsink fins 211 are assembled together in such a manner that they can move in the width direction X relative to each other, or the heatsink fins may be repositioned or positioned in a plurality of positions. Accordingly, the size of at least one air passage in the width direction X may be adjusted or changed to allow the corresponding heat generation device 300 to be at least partially inserted and positioned therein.

Each heatsink fin 211 has opposite bottom and top ends in the height direction Z of the heatsink assembly 210. The plurality of heatsink fins 211 of each heatsink assembly 210 are fixedly or detachably assembled together at one or both of the bottom and top ends. The plurality of heatsink fins 211 of each heatsink assembly 210 may be assembled together in a variety of manners. For example, the plurality of heatsink fins 211 may be interlocked or embedded together in a zipper manner or may be connected or joined with each other by other connection mechanisms or joining structures.

In the illustrated embodiments, as shown in FIGS. 1, 4, and 5, the plurality of heatsink fins 211 include a first heatsink fin 2111 and a second heatsink fin 2112. The first heatsink fin 2111 has a roughly plate-shaped body 21111 and a first spacer 21112 extending transversely (e.g., in the width direction X) from a low end and/or top end of the plate-shaped body 21111. The second heatsink fin 2112 has a roughly plate-shaped body 21121 and a second spacer 21122 extending transversely (e.g., in the width direction X) from a low end and/or a top end of the plate-shaped body 21121, respectively. The spacer may be formed on one or both sides of each plate-shaped body in the width direction, and all spacers extend in the same direction or opposite directions to each other. Adjacent first heatsink fins 2111 are assembled together to form the first passage 212, and the first spacer 21112 of one first heatsink fin 2111 is abutted against the other first heatsink fin 2111, so that the size or width of the first passage 212 in the width direction X is defined by a size or width of the first spacer 21112 in the width direction X. Similarly, adjacent first heatsink fin 2111 and second heatsink fin 2112 are assembled together to form the second passage 213, and the second spacer 21122 of the second heatsink fin 2112 is abutted against the first heatsink fin 2111, so that the size or width of the second passage 213 in the width direction X is defined by a size or width of the second spacer 21122 in the width direction X.

A first protrusion 21113 and a corresponding first opening 21114 are formed on the first spacer 21112 at the top and/or bottom end of each first heatsink fin 2111, and the plate-shaped main body 21111 is formed with a first stop 21115. The first protrusion 21113 protrudes from the first spacer 21112 in the width direction X, for example in a battlement shape, the first opening 21114 penetrates through the first spacer 21112 in a thickness direction Z, and the first stop 21115 protrudes outwardly in the thickness direction Z. The first protrusion 21113, the corresponding first opening 21114, and the first stop 21115 are arranged in sequence in the width direction X, so that their positions are aligned with each other in the width direction X. Similarly, a second protrusion 21123 and a corresponding second opening 21124 are formed on the second spacer 21122 at the top and/or low end of each second heatsink fin 2112, and the plate-shaped main body 21121 is formed with a second stop 21125. The second protrusion 21123 protrudes from the second spacer 21122 in the width direction X, for example in a battlement shape, the second opening 21124 penetrates through the second spacer 21122 in the thickness direction Z, and the second stop 21125 protrudes outwardly in the thickness direction Z. The second protrusion 21123, the corresponding second opening 21124, and the second stop 21125 are arranged in sequence in the width direction X, so that their positions are aligned with each other in the width direction X.

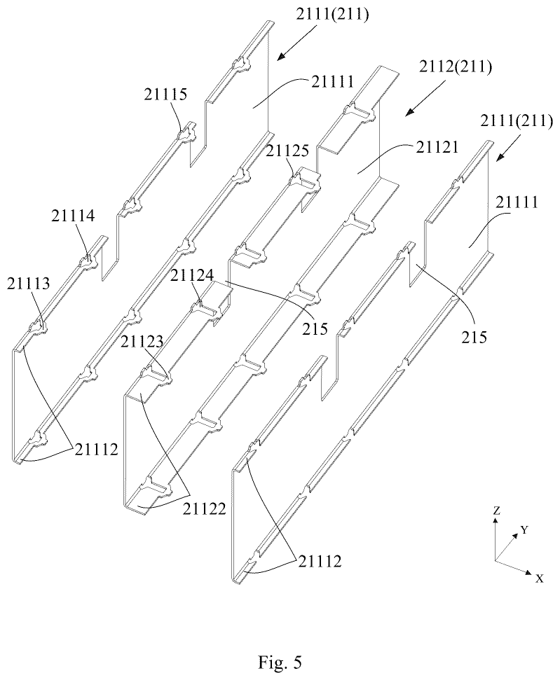

When assembling the heatsink fins, the first protrusion 21113 of one first heatsink fin of the two adjacent first heatsink fins 2111 is engaged with the first opening 21114 of the other first heatsink fin, and the first stop 21115 of the first heatsink fin is inserted into the first opening 21114 of the one first heatsink fin. This limits or prevents the movement of the two first heatsink fins relative to each other in the longitudinal direction Y and width direction X. Similarly, when assembling adjacent first heatsink fin 2111 and second heatsink fin 2112, description is made by taking the first heatsink fin 2111 being positioned on a side of the second heatsink fin 2112 away from the second spacer 21122 in the width direction X in as shown in FIG. 5. The first protrusion 21113 of the first heatsink fin 2111 is engaged with (e.g., inserted into) the second opening 21124 of the second heatsink fin 2112, and the second stop 21125 of the second heatsink fin 2112 is inserted into the first opening 21114 of the first heatsink fin 2111. This limits or prevents the movement of the two heatsink fins relative to each other in the longitudinal direction Y and width direction X. The assembly may be carried out at at least one of the top and bottom ends of each heatsink fin.

In the illustrated embodiments, as shown in FIGS. 1-4, the heatsink 200 may further include a heat transferring base plate 220 on which the plurality of heatsink fins 211 are arranged. For example, the plurality of heatsink fins 211 are in direct contact with or directly attached to the base plate 220 or connected to the base plate 220 by a heat conductive adhesive, welding, or other manner. The heat transferring base plate 220 is adapted to be installed on the housing 110 of the connector 100 to conduct heat from the connector 100 to the plurality of heatsink fins 211. As shown in the figures, the installation surface 111 of the housing 110 may be formed with an opening 113 communicated with the accommodating cavity 101, and the heat transferring bottom plate 220 may cover at least the opening 113, for example, the heat transferring bottom plate 220 may be in contact with the heat generation device or module inside the accommodating cavity 101 to effectively transfer heat.

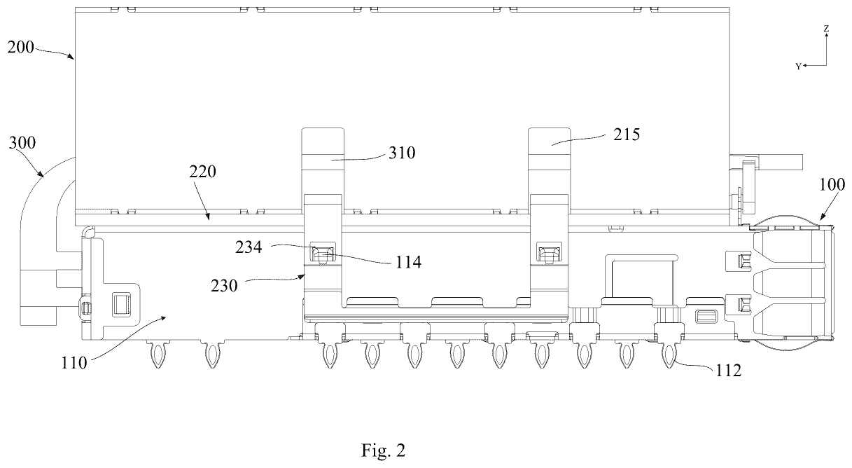

Still referring to FIGS. 1-4, the connector assembly 10 or its heatsink 200 may further include a holding member 230 adapted to be engaged with the plurality of heatsink fins 211, the heat transferring base plate 220 and the housing 110 of the connector 100 to fixedly hold the plurality of heatsink fins 211 and the heat transferring base plate 220 relative to the housing 110. Illustratively, as shown in FIGS. 1 and 2, the housing 110 may be formed with a first engagement structure 114 such as a protrusion. The holding member 230 may be formed with a second engagement structure 234 such as an opening, which is engaged or snapped with the first engagement structure 114 to fix the heatsink 200 onto the housing 110. The holding member may include an elastic member such as an elastic clip.

As shown in FIGS. 1, 2, 4, and 5, each heatsink fin 211 may be formed with a groove 215 penetrating through the heatsink fin in the width direction X. The grooves 215 of the plurality of heatsink fins 211 of each heatsink assembly 210 may be aligned with each other in the width direction X. This allows the holding member 230 to pass through the grooves 215 to fix the plurality of heatsink fins 211 and the heat transferring base plate 220 onto the housing 110.

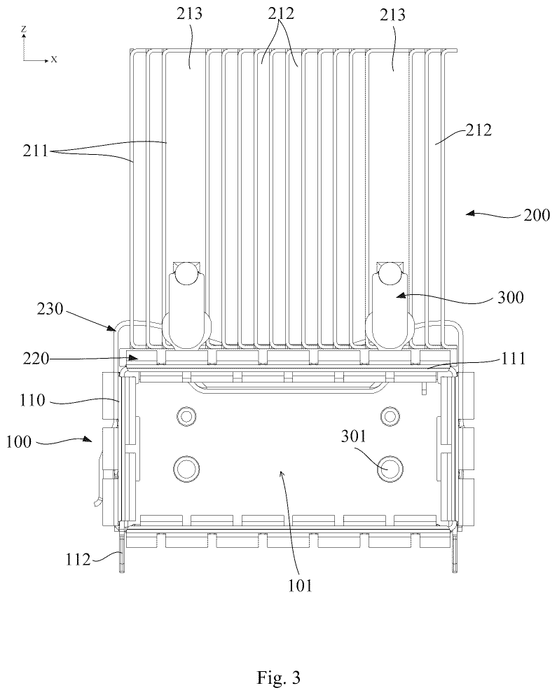

In some examples, as shown in FIGS. 2 and 3, a portion of the holding member 230 passing through the grooves 215 in the width direction X may be positioned close to the heat transferring base plate 220. In this way, the main body portion 310 of the heat generation device 300 positioned in the air passage 213 is positioned above the portion of the holding member 230, thereby facilitating the insertion of the heat generation device 300 into the second passage 213.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A heatsink adapted to be installed on a housing of a connector, comprising:
at least one heatsink assembly including a plurality of heatsink fins extending in a longitudinal direction of the heatsink assembly, the plurality of heatsink fins stacked in a spaced manner in a width direction of the heatsink assembly and assembled together to define an air passage extending in the longitudinal direction between adjacent heatsink fins,
wherein at least one of a plurality of air passages defined by the plurality of heatsink fins is sized to allow a longitudinally extending heat generation device to at least partially pass through and be positioned within a corresponding one of the at least one air passage.

2. The heatsink according to claim 1, wherein the sizes of the other air passages of the plurality of air passages in the width direction are distinct from that of the at least one air passage in the width direction and prevent the heat generation device from being positioned within the other air passages.

3. The heatsink according to claim 2, wherein the size of the at least one air passage in the width direction is greater than the sizes of the other air passages in the width direction.

4. The heatsink according to claim 3, wherein the plurality of air passages include a plurality of first passages and at least one second passage, wherein the at least one air passage comprises the at least one second passage.

5. The heatsink according to claim 4, wherein the sizes of the plurality of first passages in the width direction are the same as each other and are smaller than the size of the second passage in the width direction so as to allow only the heat generation device to be positioned within the second passage.

6. The heatsink according to claim 5, wherein each second passage is positioned between adjacent first passages in the width direction.

7. The heatsink according to claim 6, wherein the at least one second passage comprises two second passages spaced apart in the width direction, and the number of the first passages between the two second passages is more than the number of the first passages positioned outside of each second passage.

8. The heatsink according to claim 1, wherein the plurality of heatsink fins of each heatsink assembly are fixedly assembled together such that spacings between the plurality of heatsink fins in the width direction are constant.

9. The heatsink according to claim 1, wherein the plurality of heatsink fins of each heatsink assembly are movable relative to each other in the width direction, spacings between the plurality of heatsink fins in the width direction are adjustable to adjust the size of at least one air passage in the width direction to allow the corresponding heat generation device to be positioned therein.

10. The heatsink according to claim 1, wherein each heatsink fin has opposite bottom and top ends in a height direction of the heatsink assembly, and the plurality of heatsink fins of each heatsink assembly are fixedly or detachably assembled together at one of the bottom and top ends.

11. The heatsink according to claim 1, further comprising a heat transferring base plate on which the plurality of heatsink fins are arranged, the heat transferring base plate adapted to be installed on the housing of the connector to conduct heat from the connector to the plurality of heatsink fins.

12. The heatsink according to claim 11, wherein the heatsink further comprises a holding member adapted to be engaged with the plurality of heatsink fins, the heat transferring base plate, and the housing of the connector so as to fixedly hold the plurality of heatsink fins and the heat transferring base plate relative to the housing.

13. The heatsink according to claim 12, wherein each heatsink fin is formed with a groove penetrating through the heatsink fin in the width direction.

14. The heatsink according to claim 13, wherein the grooves of the plurality of heatsink fins of each heatsink assembly are aligned with each other in the width direction to allow the holding member to pass through the grooves and to fix the plurality of heatsink fins and the heat transferring base plate onto the housing.

15. The heatsink according to claim 14, wherein a portion of the holding member passing through the grooves in the width direction is positioned close to the heat transferring base plate.

16. The heatsink according to claim 15, wherein the main body portion of the heat generation device positioned in the at least one air passage is positioned above the portion of the holding member.

17. A connector assembly comprising:
a connector including a housing defining an accommodating cavity adapted to accommodate a connector module and receive an insertion module of a mating connector; and
a heatsink installed on the housing to at least dissipate heat from the connector module or insertion module positioned in the accommodating cavity, including:
at least one heatsink assembly including a plurality of heatsink fins extending in a longitudinal direction of the heatsink assembly, the plurality of heatsink fins stacked in a spaced manner in a width direction of the heatsink assembly and assembled together to define an air passage extending in the longitudinal direction between adjacent heatsink fins, at least one of a plurality of air passages defined by the plurality of heatsink fins is sized to allow a longitudinally extending heat generation device to at least partially pass through and be positioned within a corresponding one of the at least one air passage.

18. The connector assembly of claim 17, further comprising a heat generation device extending in the longitudinal direction and at least partially passing through and positioned within a corresponding one of the at least one air passage.

19. The connector assembly of claim 18, wherein the heat generation device is connected to the connector module.

20. The connector assembly according to claim 19, wherein the connector is a socket connector, and the heat generation device includes a light guide tube.
